(19) United States
(12) Patent Application Publication
(10) Pub. No.: US 2026/0362620 A1
(43) Pub. Date: Nov. 12, 2026

(54) CABINET AND SERVER SYSTEM

(71) Applicant: Fulian Precision Electronics (Tianjin) Co., LTD., Tianjin (CN)

(72) Inventors: YEN-CHEN SU, New Taipei (TW); CHIEH-HSIANG LIN, New Taipei (TW)

(21) Appl. No.: 19/422,807

(22) Filed: Dec. 17, 2025

(30) Foreign Application Priority Data
May 12, 2025 (CN) 202510604730.0

(51) Int. Cl. H05K 7/14; H05K 7/18

(52) U.S. Cl. CPC H05K 7/1411; H05K 7/1415; H05K 7/1489; H05K 7/18

(57) ABSTRACT

A server cabinet insertable into a rack includes a main body having a first shaft and a second shaft. A latch is rotatably mounted on the first shaft and movable between latching and unlatching positions, with a latching notch positioned externally to the main body. A lever is rotatably mounted on the second shaft and movable between pushed-in and pulled-out positions. A connecting rod rotatably connects the latch and lever via third and fourth shafts, respectively, with all shafts having parallel axes. The lever drives the latch via the connecting rod. In the pushed-in position, the axes of the second, third, and fourth shafts are coplanar, forming a self-locking mechanism. The rack includes a pillar; in the unlatching position, the pillar can enter or exit the notch, while in the latching position, the pillar is retained therein to secure the cabinet.

### BACKGROUND

In the current server system, in order to make the cabinet more conveniently installed into the rack, the cabinet usually has a handle, the handle is used to provide a labor-saving effect for installing or disassembling the cabinet, and after the cabinet is installed in the rack, the handle engages with the rack to position the cabinet, but the handle usually has the problem of insufficient clamping force, leading to insufficient stability in the positioning of the cabinet.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is an isometric view of a server and a pillar in an embodiment of the present application.

FIG. 2 is an isometric view of a main body shown in FIG. 1 when a lever is in a pushed-in position.

FIG. 3 is a top view of the main body shown in FIG. 2 when the lever is in the pushed-in position.

FIG. 4 is an isometric view of the main body shown in FIG. 1 when a lever is in a pushed-out position.

FIG. 5 is a top view of the main body shown in FIG. 4 when the lever is in the pushed-out position.

### DETAILED DESCRIPTION

It will be appreciated that for simplicity and clarity of illustration, where appropriate, reference numerals have been repeated among the different FIG. to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, baffle structures, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The present disclosure, including the accompanying drawings, is illustrated by way of examples and not by way of limitation. Several definitions that apply throughout this disclosure will now be presented. It should be noted that references to “an” or “one” embodiment in this disclosure are not necessarily to the same embodiment, and such references mean “at least one”.

The term “comprising” means “including, but not necessarily limited to;” it specifically indicates open-ended inclusion or membership in a so-described combination, group, series, and the like.

Without a given definition otherwise, all terms used have the same meaning as commonly understood by those skilled in the art. The terms used herein in the description of the present disclosure are for the purpose of describing specific embodiments only, and are not intended to limit the present disclosure.

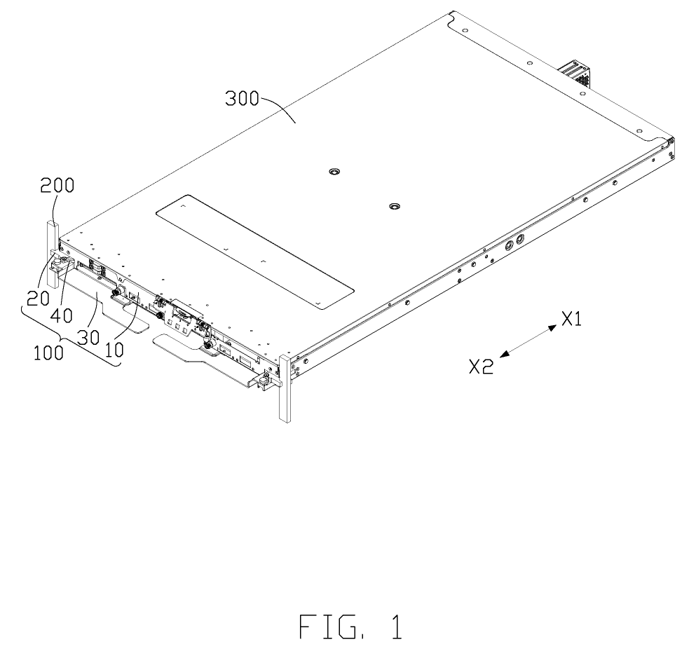

As shown in FIG. 1, an embodiment of the present application provides a cabinet 100 and a server system, wherein the server system includes a rack and a plurality of servers 300, the rack has multiple layers of space, each layer of space is used to accommodate one server 300, each server 300 includes a cabinet 100, the cabinet 100 serves as the main structure of the server 300, the rack has a pillar 200, when the cabinet 100 is installed in the rack, the pillar 200 is used to position the cabinet 100, preventing the server 300 from accidentally detaching from the rack.

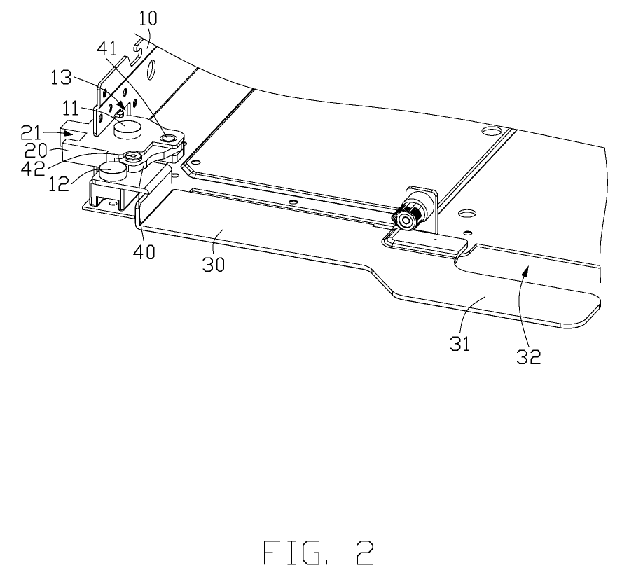

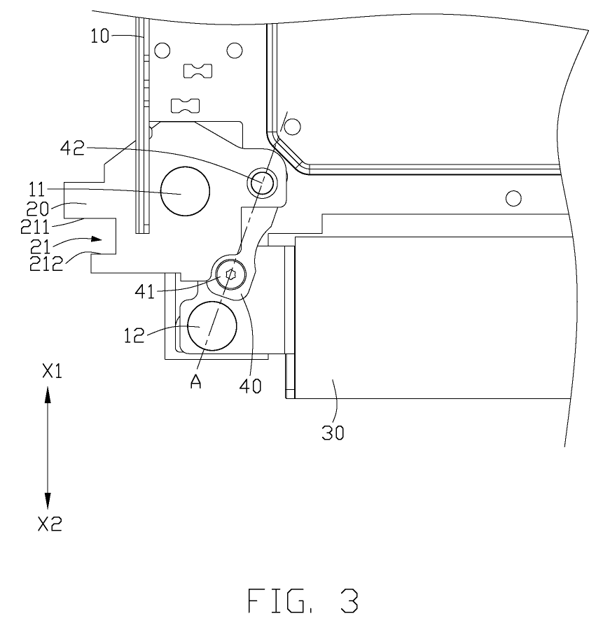

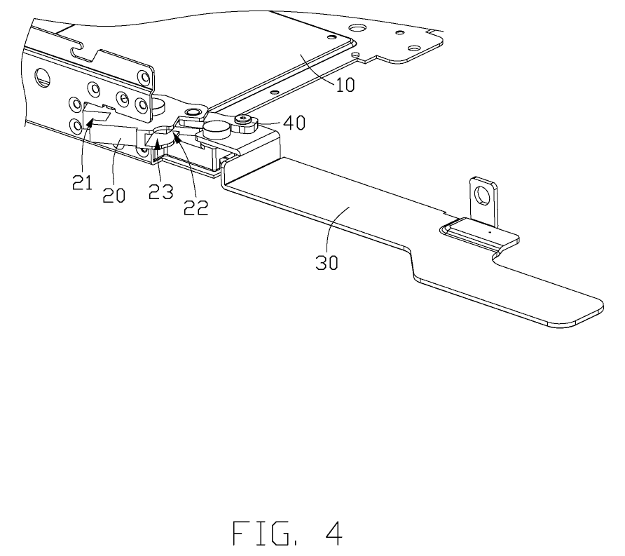

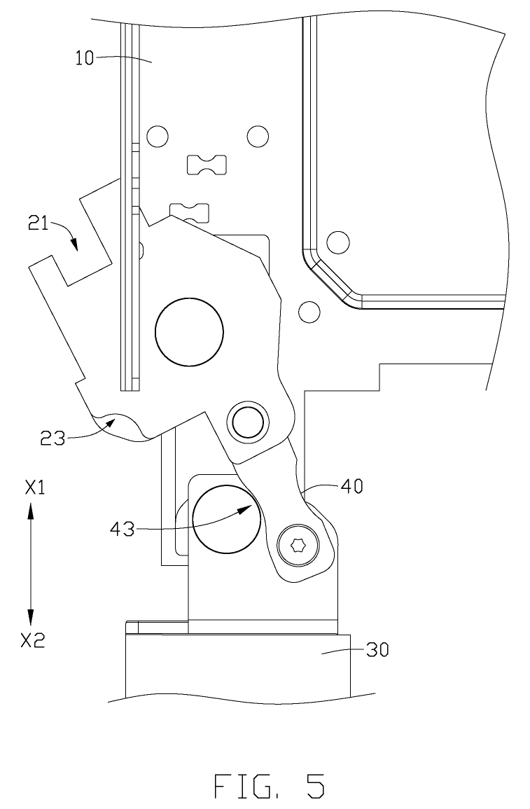

Specifically, as shown in FIGS. 2 to 5, the cabinet 100 includes a main body 10, a latch 20, a lever 30, and a connecting rod 40. The main body 10 has a first shaft 11 and a second shaft 12. The latch 20 is disposed on the first shaft 11, and the latch 20 is rotatable about the first shaft 11 between a latching position and an unlatching position, the latch 20 is provided with a latching notch 21 outside the main body 100. The lever 30 is disposed on the second shaft 12, and the lever 30 is rotatable about the second shaft 12 between a pushed-in position and a pulled-out position. The two ends of the connecting rod 40 are respectively provided with a third shaft 41 and a fourth shaft 42. One end of the connecting rod 40 is rotatably connected to the latch 20 via the third shaft 41, and the other end of the connecting rod 40 is rotatably connected to the lever 30 via the fourth shaft 42. The axes of the first shaft 11, the second shaft 12, the third shaft 41, and the fourth shaft 42 are parallel to each other. The lever 30 is used to be held by a user with bare hands, the user can rotate the lever 30, and the lever 30, when rotating, drives the latch 20 to rotate via the connecting rod 40, wherein, when the lever 30 is in the pulled-out position, the latch 20 is in the unlatching position; when the lever 30 is in the pushed-in position, the latch 20 is in the latching position. In the illustration, the server 300 is installed into the rack along a first direction X1, and the server 300 is removed from the rack along a second direction X2, the second direction X2 being the opposite direction of the first direction X1.

When a user installs the server 300 into the rack, the lever 30 is first rotated to the pulled-out position, and at the same time, the latch 20 is rotated to the unlatching position, then the server 300 is pushed inward toward the rack, so that the pillar 200 abuts against the groove wall of the latching notch 21 but does not fully enter the latching notch 21, at this time, the server 300 is also not fully installed in the rack; next, the user rotates the lever 30, so that the lever 30 turns to the pushed-in position, and at the same time, the latch 20 turns to the latching position, during the rotation of the latch 20, the pillar 200 gradually enters the latching notch 21, until after the latch 20 is in the latching position, the pillar 200 enters the latching notch 21, so that the pillar 200 is restricted within the latching notch 21, thereby fixing the position of the main body 10 relative to the pillar 200, that is, fixing the position of the server 300 relative to the rack.

When a user needs to remove the server 300 from the rack, the lever 30 is first rotated to the pulled-out position, and at the same time, the latch 20 is rotated to the unlatching position, thereby releasing the positioning of the pillar 200 on the main body 10, then the server 300 is pulled out from the rack, and the pillar 200 gradually leaves the latching notch 21.

It is worth noting that, when the lever 30 is in the pushed-in position, that is, when the latch 20 is in the latching position, the axes of the second shaft 12, the third shaft 41, and the fourth shaft 42 are located in the same plane A, thereby forming a self-lock, at this time, as long as the user does not rotate the lever 30, the latch 20 cannot rotate on its own, so that even if the latch 20 is subjected to accidental force (for example, rack shaking, etc.), it cannot drive the connecting rod 40 or the lever 30 to rotate, thereby enhancing the clamping force of the latch 20 on the pillar 200, and further improving the stability of the cabinet 100 being positioned.

In some embodiments, the side of the latch 20 facing the connecting rod 40 is provided with a slot 22, when the lever 30 is in the pushed-in position, that is, when the latch 20 is in the latching position, the connecting rod 40 is at least partially located in the slot 22, thereby avoiding interference between the latch 20 and the connecting rod 40, and at the same time, improving space utilization and reducing the volume of the server 300.

In some embodiments, the connecting rod 40 is provided with a first notch 43, when the lever 30 is in the pulled-out position, that is, when the latch 20 is in the unlatching position, the second shaft 12 is at least partially located in the first notch 43, and the connecting rod 40 avoids the second shaft 12 via the first notch 43, avoiding interference between the connecting rod 40 and the second shaft 12.

In some embodiments, the latch 20 is provided with a second notch 23, when the lever 30 is in the pushed-in position, that is, when the latch 20 is in the latching position, the fourth shaft 42 is at least partially disposed in the second notch 23, and the latch 20 avoids the fourth shaft 42 via the second notch 23, avoiding interference between the latch 20 and the fourth shaft 42.

In some embodiments, the distance between the third shaft 41 and the fourth shaft 42 is less than the distance between the first shaft 11 and the second shaft 12, since the lever 30 drives the latch 20 to rotate via the lever principle to achieve labor-saving effect, and the presence of the connecting rod 40 divides the lever into two stages, thus there is a loss of lever arm, so minimizing the length of the connecting rod 40, that is, the distance between the third shaft 41 and the fourth shaft 42, can ensure the labor-saving effect.

In some embodiments, the specific positional relationship of the latch 20, the lever 30, and the connecting rod 40 is: the first shaft 11 is disposed at the central position of the latch 20, the third shaft 41 is disposed on the side of the latch 20 away from the latching notch 21, the second shaft 12 is located on the side of the first shaft 11 and the third shaft 41 toward the second direction X2, when the lever 30 is in the pushed-in position, that is, when the latch 20 is in the latching position, the fourth shaft 42 is located on the side of the second shaft 12 toward the first direction X1; when the lever 30 is in the pulled-out position, that is, when the latch 20 is in the unlatching position, the fourth shaft 42 is located on the side of the second shaft 12 toward the second direction X2. When the lever 30 is in the pushed-in position, that is, when the latch 20 is in the latching position, the same plane A in which the axes of the second shaft 12, the third shaft 41, and the fourth shaft 42 are located intersects the first direction X1.

In some embodiments, one side of the main body 10 is provided with an avoiding slot 13, a part of the latch 20 extends out of the main body 10 through the avoiding slot 13, and the latching notch 21 is disposed on the part of the latch 20 extending out of the avoiding slot 13, the main body 10 avoids interference with the latch 20 via the avoiding slot 13.

In some embodiments, the latch 20 has a first notch surface 211 and a second notch surface 212 that are opposite and parallel within the latching notch 21, the distance between the first notch surface 211 and the second notch surface 212 is greater than the width of the pillar 200 in the first direction X1, so that there is space between the latching notch 21 and the pillar 200, to allow the latch 20 to rotate relative to the pillar 200, avoiding the latch 20 from being stuck by the pillar 200. When the latch 20 is in the latching position, the first notch surface 211 is on the side of the pillar 200 toward the first direction X1, the second notch surface 212 is on the side of the pillar 200 toward the second direction X2, and the first notch surface 211 is used to block the pillar 200, preventing the server 300 from detaching from the rack.

In some embodiments, during the process of the latch 20 turning from the latching position to the unlatching position, the second notch surface 212 abuts and pushes the side of the pillar 200 toward the second direction X2, causing the main body 10 to move along the second direction X2, thereby providing assistance, so that the main body 10 detaches from the rack, facilitating the removal of the server 300; during the process of the latch 20 turning from the unlatching position to the latching position, the first notch surface 211 abuts and pushes the side of the pillar 200 toward the first direction X1, causing the main body 10 to move along the first direction X1, thereby providing assistance, so that the main body 10 enters the rack, facilitating the installation of the server 300. Further optionally, the cross-section of the pillar 200 may be rectangular, or the cross-section of the pillar 200 may also be circular, etc.

In some embodiments, the end of the lever 30 away from the second shaft 12 is provided with a handle 31, and there is a gap 32 between the handle 31 and the main body 10, the gap 32 is used to provide space for the user to hold the handle 31 with bare hands.

In some embodiments, the rack is provided with one pillar 200 respectively on opposite sides of each server 300, opposite sides of the main body 10 of each server 300 symmetrically have a set of latch 20, lever 30, and connecting rod 40 respectively, and the latch 20 on the same side is used to clamp the pillar 200 on the same side, to more stably fix the server 300.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims.

What is claimed is:

1. A cabinet of a server insertable into a rack and comprising:
a main body comprising a first shaft and a second shaft;
a latch rotatable around the first shaft between a latching position and an unlatching position, the latch comprising a latching notch outside the main body;
a lever rotatable around the second shaft between a pushed-in position and a pulled-out position; and
a connecting rod, wherein an end of the connecting rod is rotatably connected to the latch by a third shaft, another end of the connecting rod is rotatably connected to the lever by a fourth shaft, the lever rotates the latch via the connecting rod;
wherein an axis of the first shaft, an axis of the second shaft, an axis of the third shaft and an axis of the fourth shaft are parallel, the axis of the second shaft, the axis of the third shaft, and the axis of the fourth shaft are co-planar;
wherein the rack comprises a pillar, in a case that the lever is in the pulled-out position, and that the latch is in the unlatching position, the pillar is retractable into or out of the latching notch; in a case that the lever is in the pushed-in position, and that the latch is in the latching position, the pillar is retained in the latching notch to secure the main body in the rack.

2. The cabinet of claim 1, wherein the latch comprises a slot facing to the connecting rod, in the case that the lever is in the pushed-in position and the latch is in the latching position, the connecting rod is partially inserted in the slot.

3. The cabinet of claim 1, wherein the connecting rod comprises a first notch, in the case that the lever is in the pulled-out position and the latch is in the unlatching position, the second shaft is partially inserted in the first notch.

4. The cabinet of claim 1, wherein the latch comprises a second notch, in the case that the lever is in the pushed-in position and the latch is in the latching position, the fourth shaft is partially inserted in the second notch.

5. The cabinet of claim 1, wherein a distance between the third shaft and the fourth shaft is less than a distance between the first shaft and the second shaft.

6. The cabinet of claim 5, wherein the main body is insertable into the rack in a first direction, the main body is removable from the rack in a second direction, the first direction is opposite to the second direction;
the first shaft passes through a center of the latch, the third shaft is located on a side of the latch opposite to the latching notch, the second shaft is located on a side of the first shaft and the third shaft along the second direction;
in the case that the lever is in the pushed-in position and the latch is in the latching position, the fourth shaft is located on a side of the second shaft along the first direction;
in the case that the lever is in the pulled-out position and the latch is in the unlatching position, the fourth shaft is located on a side of the second shaft along the second direction;
in the case that the lever is in the pushed-in position and the latch is in the latching position, the first direction intersects with a plane defined by the axis of the second shaft, the axis of the third shaft, and the axis of the fourth shaft.

7. The cabinet of claim 6, wherein the latch comprises a first notch surface and a second notch surface in the latching notch, the first notch surface and the second notch surface are parallel, a distance between the first notch surface and the second notch surface is larger than a width of the pillar in the first direction, in a case that the latch is in the latching position, the first notch surface is located on a side of the pillar along the first direction, the second notch surface is located on a side of the pillar along the second direction.

8. The cabinet of claim 7, wherein in response to the latch rotating from the latching position to the unlatching position, the second notch surface pushes the pillar to move the main body in the second direction; in response to the latch rotating from the unlatching position to the latching position, the first notch surface pushes the pillar to move the main body in the first direction.

9. The cabinet of claim 1, wherein the main body comprises an avoiding slot, a part of the latch extends out of the main body by the avoiding slot and the latching notch is located on the part of the latch out of the main body.

10. The cabinet of claim 1, wherein an end of the lever away from the second shaft forms a handle, and a gap is formed between the handle and the main body.

11. A server system comprising:
a rack comprising a pillar; and
a server insertable into a rack and comprising:
a cabinet comprising:
a main body comprising a first shaft and a second shaft;
a latch rotatable around the first shaft between a latching position and an unlatching position, the latch comprising a latching notch outside the main body;
a lever rotatable around the second shaft between a pushed-in position and a pulled-out position; and
a connecting rod, wherein an end of the connecting rod is rotatably connected to the latch by a third shaft, another end of the connecting rod is rotatably connected to the lever by a fourth shaft, the lever rotates the latch via the connecting rod;
wherein an axis of the first shaft, an axis of the second shaft, an axis of the third shaft and an axis of the fourth shaft are parallel, the axis of the second shaft, the axis of the third shaft, and the axis of the fourth shaft are co-planar;
wherein the rack comprises a pillar, in a case that the lever is in the pulled-out position, and that the latch is in the unlatching position, the pillar is retractable into or out of the latching notch; in a case that the lever is in the pushed-in position, and that the latch is in the latching position, the pillar is retained in the latching notch to secure the main body in the rack.

12. The server system of claim 11, wherein the latch comprises a slot facing to the connecting rod, in the case that the lever is in the pushed-in position and the latch is in the latching position, the connecting rod is partially inserted in the slot.

13. The server system of claim 11, wherein the connecting rod comprises a first notch, in the case that the lever is in the pulled-out position and the latch is in the unlatching position, the second shaft is partially inserted in the first notch.

14. The server system of claim 11, wherein the latch comprises a second notch, in the case that the lever is in the pushed-in position and the latch is in the latching position, the fourth shaft is partially inserted in the second notch.

15. The server system of claim 11, wherein a distance between the third shaft and the fourth shaft is less than a distance between the first shaft and the second shaft.

16. The server system of claim 15, wherein the main body is insertable into the rack in a first direction, the main body is removable from the rack in a second direction, the first direction is opposite to the second direction;
the first shaft passes through a center of the latch, the third shaft is located on a side of the latch opposite to the latching notch, the second shaft is located on a side of the first shaft and the third shaft along the second direction;
in the case that the lever is in the pushed-in position and the latch is in the latching position, the fourth shaft is located on a side of the second shaft along the first direction;
in the case that the lever is in the pulled-out position and the latch is in the unlatching position, the fourth shaft is located on a side of the second shaft along the second direction;
in the case that the lever is in the pushed-in position and the latch is in the latching position, the first direction intersects with a plane defined by the axis of the second shaft, the axis of the third shaft, and the axis of the fourth shaft.

17. The server system of claim 16, wherein the latch comprises a first notch surface and a second notch surface in the latching notch, the first notch surface and the second notch surface are parallel, a distance between the first notch surface and the second notch surface is larger than a width of the pillar in the first direction, in a case that the latch is in the latching position, the first notch surface is located on a side of the pillar along the first direction, the second notch surface is located on a side of the pillar along the second direction.

18. The server system of claim 17, wherein in response to the latch rotating from the latching position to the unlatching position, the second notch surface pushes the pillar to move the main body in the second direction; in response to the latch rotating from the unlatching position to the latching position, the first notch surface pushes the pillar to move the main body in the first direction.

19. The server system of claim 11, wherein the main body comprises an avoiding slot, a part of the latch extends out of the main body by the avoiding slot and the latching notch is located on the part of the latch out of the main body.

20. The server system of claim 11, wherein an end of the lever away from the second shaft forms a handle, and a gap is formed between the handle and the main body.
